(19) United States
(12) Patent Application Publication
(10) Pub. No.: US 2008/0205504 A1
(43) Pub. Date: Aug. 28, 2008

(54) DECISION FEEDBACK EQUALIZERS AND EQUALIZING METHODS THEREOF

(76) Inventors: Yih-Ming Tsuie, Hsinchu City (TW); Yao-Tang Chou, Hsinchu City (TW); Wei-Ting Wang, Yilan City (TW)

Correspondence Address: NORTH AMERICA INTELLECTUAL PROPERTY CORPORATION, P.O. BOX 506, MERRIFIELD, VA, 22116, US

(21) Appl. No.: 11/678,624

(22) Filed: Feb. 26, 2007

(51) Int. Cl. H03K 5/159

(52) U.S. Cl. 375/233; 375/E07.236

(57) ABSTRACT

Decision feedback equalizers and related equalizing method are provided. One proposed decision feedback equalizer includes: a feed-forward filter for filtering an incoming signal to generate a filtered signal; a feedback filter for generating a feedback signal according to a decision signal; an operating device, coupled to the feed-forward filter and the feedback filter, for generating an output signal according to the filtered signal and the feedback signal; a decision device, coupled to the operating device and the feedback filter, for generating the decision signal according to the output signal; and an updating device coupled to the feedback filter for constraining coefficients of predetermined taps of the feedback filter while updating the tap coefficients of the feedback filter; wherein each predetermined tap of the feedback filter corresponds to a tap of the feed-forward filter.

### BACKGROUND

The present invention relates to digital television systems, and more particularly, to decision feedback equalizers with constrained coefficients and equalizing methods thereof.

For a digital television system, video data is transmitted from a transmitter to a receiver via a communication channel. However, the communication channel often distorts the transmitted data. For example, inter-symbol interference (ISI) caused by multi-path fading is a critical problem for the digital television system.

In the related art, a decision feedback equalizer (DFE) is typically employed by the receiver to mitigate the deleterious effects of ISI. In operations, the DFE utilizes a feedback filter to drive an estimate of the ISI distortion based on prior detected symbols. The DFE can effectively remove the ISI distortion if the detected symbols are reliable. Otherwise, errors in the detected symbols propagate to the distortion estimate and degrade the performance of the DFE. In view of the foregoing, it can be appreciated that a substantial need exists for methods and apparatuses that can effectively reduce the error propagation in the DFE.

### SUMMARY

An exemplary embodiment of a decision feedback equalizer is disclosed comprising: a feed-forward filter for filtering an incoming signal to generate a filtered signal; a feedback filter for generating a feedback signal according to a decision signal; an operating device, coupled to the feed-forward filter and the feedback filter, for generating an output signal according to the filtered signal and the feedback signal; a decision device, coupled to the operating device and the feedback filter, for generating the decision signal according to the output signal; and an updating device coupled to the feedback filter for constraining coefficients of predetermined taps of the feedback filter while updating the tap coefficients of the feedback filter; wherein each predetermined tap of the feedback filter corresponds to a tap of the feed-forward filter.

An exemplary embodiment of a method for equalizing an incoming signal is disclosed comprising: utilizing a feed-forward filter to filter the incoming signal to generate a filtered signal; utilizing a feedback filter to generate a feedback signal according to a decision signal; generating an output signal according to the filtered signal and the feedback signal; generating the decision signal according to the output signal; and constraining coefficients of predetermined taps of the feedback filter while updating the tap coefficients of the feedback filter in which each predetermined tap of the feedback filter corresponds to a tap of the feed-forward filter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified block diagram of a decision feedback filter (DFE) according to a first embodiment.

FIG. 2 is a schematic diagram illustrating a timing relationship between a tap delay line of the feed-forward filter of FIG. 1 and a tap delay line of the feedback filter of FIG. 1 according to an exemplary embodiment.

FIG. 3 is a schematic diagram illustrating the constraint level of tap coefficient within a constraint region with respect to different operating states according to an embodiment.

FIG. 4 is a block diagram of the updating device of FIG. 1 according to a first embodiment.

FIG. 5 is a block diagram of the constraint level generator of FIG. 4 according to an exemplary embodiment.

FIG. 6 is a block diagram of the coefficient updater of FIG. 4 according to an exemplary embodiment.

FIG. 7 is a block diagram of the updating device of FIG. 1 according to a second embodiment.

FIG. 8 is a block diagram of the updating device of FIG. 1 according to a third embodiment.

FIG. 9 is a simplified block diagram of a DFE according to a second embodiment.

FIG. 10 is a schematic diagram of the linear predictor of FIG. 9 according to an exemplary embodiment.

### DETAILED DESCRIPTION

Certain terms are used throughout the description and following claims to refer to particular components. As one skilled in the art will appreciate, electronic equipment manufacturers may refer to a component by different names. This document does not intend to distinguish between components that differ in name but not in function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

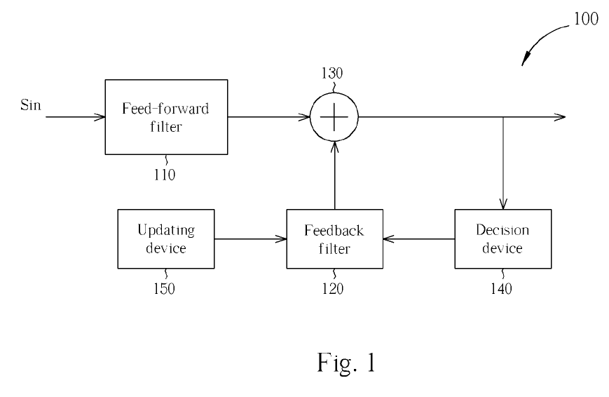

Please refer to FIG. 1, which shows a simplified block diagram of a decision feedback equalizer (DFE) 100 according to a first embodiment of the present invention. The DFE 100 comprises a feed-forward filter 110; a feedback filter 120; an operating device 130 coupled to the feed-forward filter 110 and the feedback filter 120; a decision device 140 coupled to the operating device 130 and the feedback filter 120; and an updating device 150 coupled to the feedback filter 120. Hereinafter, operations of the DFE 100 will be described in more detail.

In the DFE 100, the feed-forward filter 110 is arranged for filtering an incoming signal Sin to generate a filtered signal. The feedback filter 120 is arranged for generating a feedback signal according to a decision signal. The feed-forward filter 110 and the feedback filter 120 may each be implemented as a FIR filter. The operating device 130 generates an output signal according to the filtered signal generated by the feed-forward filter 110 and the feedback signal generated by the feedback filter 120. The decision device 140 generates the decision signal according to the output signal generated by the operating device 130, and applies the decision signal into the feedback filter 120. In this embodiment, the operating device 130 simply combines the filtered signal and the feedback signal to generate the output signal. Accordingly, the operating device 130 can be realized using an adder. In addition, the decision device 140 typically comprises a slicer for slicing the output signal of the DFE 100 to generate the decision signal.

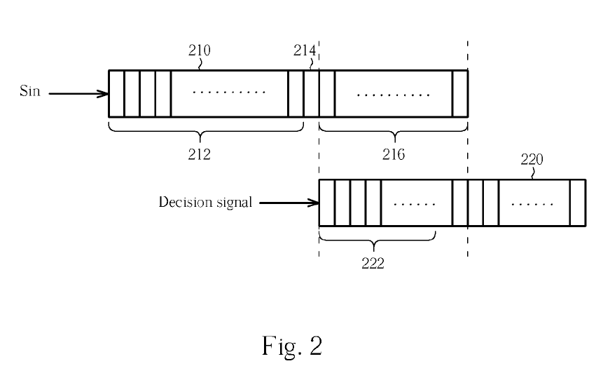

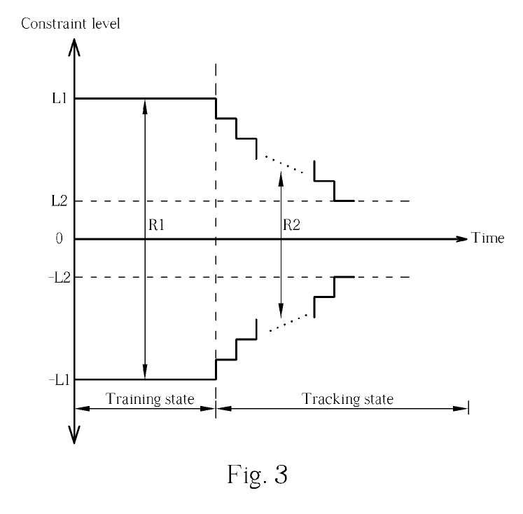

The updating device 150 is arranged for updating the tap coefficients of the feedback filter 120. In order to mitigate the error propagation of the DFE 100, the updating device 150 of this embodiment constrains coefficients of predetermined taps of the feedback filter 120 while updating the tap coefficients of the feedback filter 120, wherein each predetermined tap of the feedback filter 120 corresponds to a tap of the feed-forward filter 110. Hereinafter, the operations of the updating device 150 are described in detail with reference to FIG. 2 and FIG. 3.

FIG. 2 shows a schematic diagram illustrating a timing relationship between a tap delay line 210 of the feed-forward filter 110 and a tap delay line 220 of the feedback filter 120 according to an exemplary embodiment. The tap delay line 210 of the feed-forward filter 110 comprises a first tap set 212, a main tap 214, and a second tap set 216, wherein the main tap 214 is positioned between the first tap set 212 and the second tap set 216. In this case, the first tap set 212 of the feed-forward filter 110 comprises a tap for receiving the incoming signal Sin. As shown in FIG. 2, the tap delay line 220 of the feedback filter 120 partially overlaps the tap delay line 210 of the feed-forward filter 110. The overlap between the tap delay line 210 and the tap delay line 220 is denoted by two dotted lines in FIG. 2.

In operations, the updating device 150 constrains the coefficients of a plurality of predetermined taps of the tap delay line 220 of the feedback filter 120 while updating the tap coefficients of the feedback filter 120. Specifically, the plurality of predetermined taps of the tap delay line 220 overlap a plurality of taps of the second tap set 216 of tap delay line 210. In a preferred embodiment, the predetermined taps of the feedback filter 120 are consecutive and form a constraint region 222 beginning from the leftmost tap (i.e. that tap for receiving the decision signal of the tap delay line 220.

In one embodiment, the tap number of the constraint region 222 is less than the tap number of the second tap set 216 of the tap delay line 210. That is, the length of the constraint region 222 of the feedback filter 120 is shorter than the length of the second tap set 216 of the feed-forward filter 110.

In another embodiment, the sum of the tap number of the constraint region 222 of the feedback filter 120 and the tap number of the second tap set 216 of the feed-forward filter 110 is less than the total tap number of the feedback filter 120. That is, the length of the tap delay line 220 of the feedback filter 120 is greater than the sum of the length of the constraint region 222 and the length of the second tap set 216 in such a scheme.

In another embodiment, the length of the constraint region 222 of the feedback filter 120 is designed to satisfy the above two conditions. In other words, the length of the constraint region 222 is shorter than the length of the second tap set 216, and the length of the tap delay line 220 is greater than the sum of the length of the constraint region 222 and the length of the second tap set 216 in this embodiment.

As is well known in the art, the operations of the DFE 100 involve two operating states: a training state and a tracking state. During the training state, the updating device 150 constrains the coefficient of each predetermined tap of the constraint region 222 of the feedback filter 120 within a first range. On the other hand, the updating device 150 constrains the coefficient of each predetermined tap of the constraint region 222 within a second range that is narrower than the first range during the tracking state. That is, the coefficient of each predetermined tap within the constraint region 222 of the feedback filter 120 has different constraint levels in different operating states of the DFE 100.

FIG. 3 shows a schematic diagram illustrating the constraint level of tap coefficient within the constraint region 222 with respect to different operating states according to an embodiment of the present invention. As illustrated in FIG. 3, the updating device 150 constrains the coefficient of each predetermined tap of the constraint region 222 within a first range R1 ranging from L1 to −L1 during the training state of the DFE 100. When the operation of the DFE 100 is switched to the tracking state, the updating device 150 constrains the coefficient of each predetermined tap of the constraint region 222 within a second range R2 that is narrower than the first range R1. In this embodiment, the updating device 150 gradually narrows the second range R2 during the tracking state until the second range R2 reaches a predetermined range from L2 to −L2.

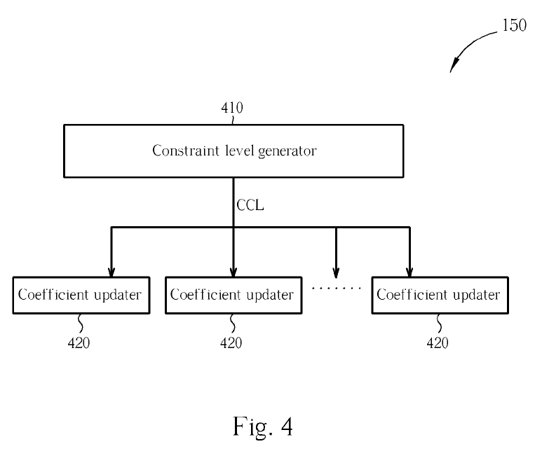

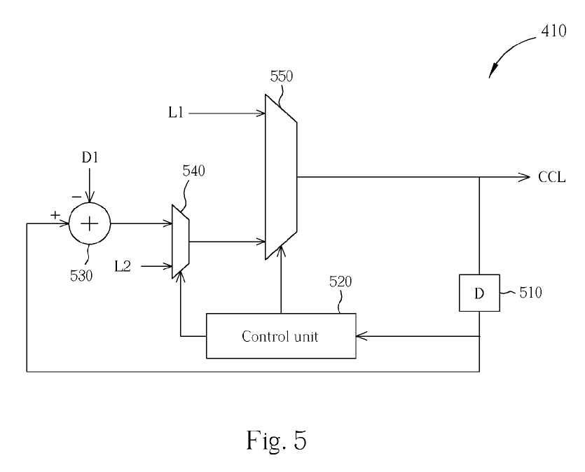

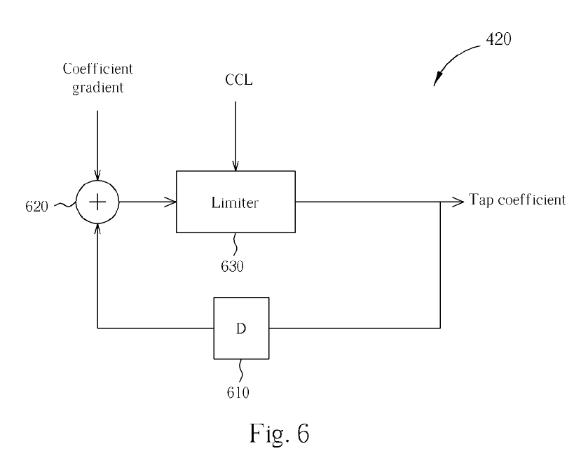

FIG. 4 depicts a block diagram of the updating device 150 according to a first embodiment. In this embodiment, the updating device 150 comprises a constraint level generator 410 and at least one coefficient updater 420 coupled to the constraint level generator 410. The constraint level generator 410 generates a current constraint level CCL corresponding to either the first range R1 or the second range R2 illustrated in FIG. 3. Each coefficient updater 420 is arranged for updating the coefficient of a predetermined tap of the constraint region 222 of the feedback filter 120 according to the current constraint level CCL. Operations and implementations of the updating device 150 will be explained in detail below with reference to FIG. 5 and FIG. 6.

FIG. 5 is a block diagram of the constraint level generator 410 of FIG. 4 according to an exemplary embodiment. As shown in FIG. 5, the constraint level generator 410 comprises a delay unit 510; a control unit 520 coupled to the delay unit 510; a subtracter 530 coupled to the delay unit 510; a first selector 540 coupled to the subtracter 530 and the control unit 520; and a second selector 550 coupled to the first selector 540, the delay unit 510, and the control unit 520. During the training state, the control unit 520 controls the second selector 550 to output a first predetermined level L1 as the current constraint level CCL. During the tracking state, the control unit 520 controls the second selector 550 to select the output of the first selector 540 as the current constraint level CCL.

In the tracking state, the delay unit 510 delays a preceding constraint level outputted by the second selector 550 to provide a delayed constraint level. The control unit 520 determines if the delayed constraint level is greater than a second predetermined level L2. If the delayed constraint level is less than or equal to the second predetermined level L2, then the control unit 520 controls the first selector 540 to select the second predetermined level L2 as output. On the other hand, if the delayed constraint level is greater than the second predetermined level L2, the subtracter 530 subtracts a predetermined value D1 from the delayed constraint level (i.e., the preceding constraint level) to generate a candidate constraint level, and the control unit 520 controls the first and second selectors 540 and 550 to output the candidate constraint level as the current constraint level CCL. As a result, the coefficient constraint range of the constraint region 222 of the feedback filter 120 is gradually narrowed by the updating device 150.

In practice, each of the first and second selectors 540 and 550 may be implemented using a multiplexer. Additionally, the predetermined value D1 may be a fixed value or a variable that varies with the time.

FIG. 6 shows a block diagram of the coefficient updater 420 of FIG. 4 according to an exemplary embodiment. The coefficient updater 420 of this embodiment comprises: a delay unit 610 for delaying a preceding tap coefficient of a predetermined tap of the constraint region 222 of the feedback filter 120 to provide a delayed tap coefficient; a calculating unit 620 coupled to the delay unit 610 for calculating a tap coefficient according to a coefficient gradient and the delay tap coefficient (i.e., the preceding tap coefficient); and a limiter 630 coupled to the calculating unit 620 for limiting the absolute value of the tap coefficient generated by the calculating unit 620 according to the current constraint level CCL generated by the constraint level generator 410 to generate a current tap coefficient for the predetermined tap. In one aspect, the coefficient update operation performed by the coefficient updater 420 can be expressed as:

w_{—}tmp(n+1)=w(n)+α*e(n)*x(n) (1)

w(n+1)=clamp[w_{—}tmp(n+1)] (2)

where n is the time index; w(n) is the tap coefficient vector of the predetermined tap of the constraint region 222 of the feedback filter 120; w_tmp(n+1) is a temporary tap coefficient vector generated by the calculating unit 620; α is a step size; e(n) is a difference between the decision signal and the output signal; x(n) is a corresponding input vector of the feedback filter 120; w(n+1) is the current tap coefficient vector for the predetermined tap; and the item α*e(n)*x(n) is the coefficient gradient employed by the calculating unit 620.

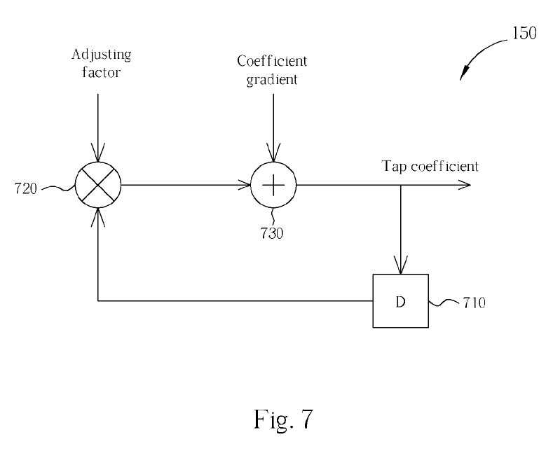

In practical implementations, the updating device 150 of FIG. 1 may generate a current tap coefficient for a predetermined tap of the constraint region 222 of the feedback filter 120 by applying a leakage function to erode a preceding tap coefficient of the predetermined tap during the tracking state of the DFE 100. By way of example, FIG. 7 shows a block diagram of the updating device 150 of FIG. 1 according to a second embodiment. In this embodiment, the updating device 150 comprises: a delay unit 710 for delaying a preceding tap coefficient of the predetermined tap of the constraint region 222 of the feedback filter 120 to provide a delayed tap coefficient; a multiplier 720 coupled to the delay unit 710 for multiplying the preceding tap coefficient by an adjusting factor to generate a product; and an adder 730 coupled to the multiplier 720 for adding the product to a coefficient gradient to generate a current tap coefficient for the predetermined tap. The operation of the updating device 150 of this embodiment can be expressed as follows:

w(n+1)=(1−αβ)w(n)+α*e(n)*x(n) (3)

where n, w(n), α, e(n), and x(n) are as defined above. α is a parameter for controlling the “leakage” amount of tap coefficient, and the item (1−αβ) is the adjusting factor employed by the multiplier 720. In a preferred embodiment, the parameter β is greater than one.

As can be derived from the equation (3), the updating device 150 illustrated in FIG. 7 erodes the preceding tap coefficient of the predetermined tap of the constraint region 222 to generate an updated tap coefficient for the predetermined tap during the tracking state.

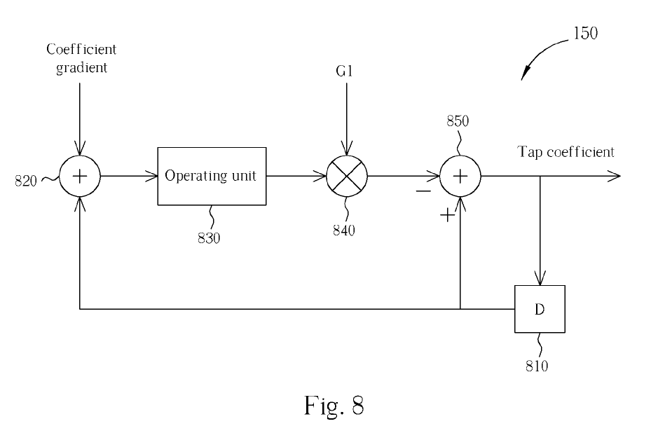

Please refer to FIG. 8, which shows a block diagram of the updating device 150 of FIG. 1 according to a third embodiment. In this embodiment, the updating device 150 comprises: a delay unit 810 for delaying a preceding tap coefficient of the predetermined tap of the constraint region 222 of the feedback filter 120 to provide a delayed tap coefficient; a calculating unit 820 coupled to the delay unit 810 for calculating a tap coefficient according to a coefficient gradient and the preceding tap coefficient of the predetermined tap; an operating unit 830 coupled to the calculating unit 820 for applying a sign function on the tap coefficient generated by the calculating unit 820 to generate a sign value; a multiplier 840 coupled to the operating unit 830 for multiplying the sign value by a predetermined value G1 to generate a product; and a subtracter 850 coupled to the multiplier 840 for subtracting the product from the preceding tap coefficient to generate a current tap coefficient for the predetermined tap of the constraint region 222 of the feedback filter 120. The operation of the updating device 150 of this embodiment can be expressed as follows:

w_{—}tmp(n+1)=w(n)+α*e(n)*x(n) (4)

w(n+1)=w(n)−sign[w_{—}tmp(n+1)]*G1 (5)

where n, w(n), α, e(n), and x(n) are as defined above, and w_tmp(n+1) is a temporary coefficient vector generated by the calculating unit 820. In a preferred embodiment, the predetermined value G1 is fixed.

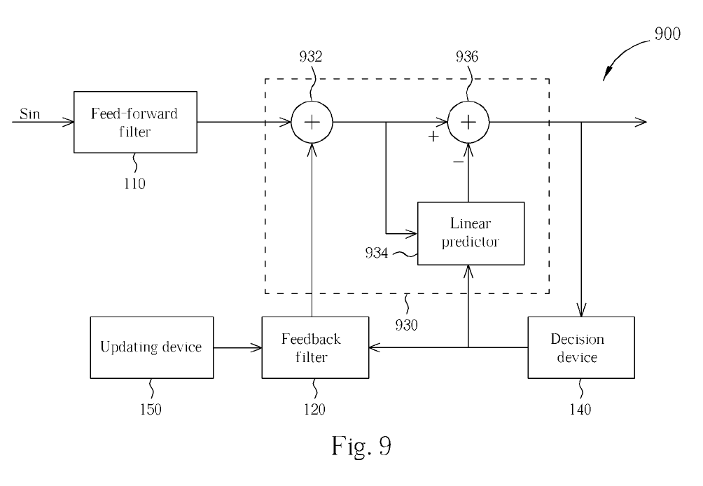

Please refer to FIG. 9, which depicts a simplified block diagram of a decision feedback filter (DFE) 900 according to a second embodiment of the present invention. The DFE 900 is similar to the aforementioned DFE 100, so components having the same operations and implementations are labeled the same for the sake of clarity. The difference between the DFE 100 and the DFE 900 is that an operating device 930 of the DFE 900 differs from the operating device 130 of the DFE 100. As shown in FIG. 9, the operating device 930 of the DFE 900 comprises an adder 932; a linear predictor 934 coupled to the adder 932 and the decision device 140; and a subtracter 936 coupled to the adder 932 and the linear predictor 934.

The adder 932 is utilized for adding the filtered signal generated by the feed-forward filter 110 and the feedback signal generated by the feedback filter 120 to generate a data signal. The linear predictor 934 is arranged for estimating decision errors made by the decision device 140 according to the decision signal generated by the decision device 140 and the data signal. The subtracter 936 is used for subtracting the estimated decision errors from the data signal to generate an output signal.

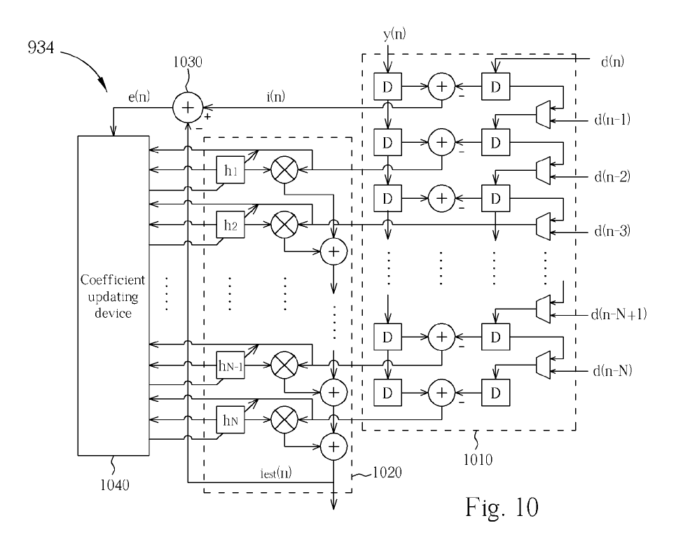

FIG. 10 is a schematic diagram of the linear predictor 934 of FIG. 9 according to an exemplary embodiment. In this embodiment, the linear predictor 934 comprises: a decision error calculator 1010 for calculating a plurality of decision error values according to the data signal and the decision signal; a decision error estimator 1020 coupled to the decision error calculator 1010 for generating an estimate value according to the plurality of decision error values and a plurality of tap coefficients; a subtracter 1030, coupled to the decision error calculator 1010 and the decision error estimator 1020, for subtracting the estimate value from a decision error value generated by the decision error calculator 1010 to generate an error value; and a coefficient updating device 1040, coupled to the subtracter 1030 and the decision error estimator 1020, for updating the plurality of tap coefficients of the decision error estimator 1020 according to the error value and the plurality of decision error values. In practice, the decision error estimator 1020 can be implemented by using a digital filter.

The coefficient update operation of the decision error estimator 1020 made by the coefficient updating device 1040 can be expressed as follows:

H(n−1)=[h₁(n−1),h₂(n−1), . . . ,h_{N}(n−1)]^{T} (6)

Y(n−1)=[y(n−1),y(n−2), . . . ,y(n−N)]^{T} (7)

D(n−1)=[d(n−1),d(n−2), . . . ,d(n−N)]^{T} (8)

I(n−1)=Y(n−1)−D(n−1) (9)

iₑₛₜ(n)=H^{T}(n−1)I(n−1) (10)

i(n)=y(n)−d(n) (11)

e′(n)=i(n)−iₑₛₜ(n) (12)

H(n)=H(n−1)+μ*I(n−1)*e′(n) (13)

where H(n−1) is a tap coefficient vector of the decision error estimator 1020; Y(n−1) is the output signal of the DFE 900; D(n−1) is the decision signal generated by the decision device 140; I(n−1) is a decision error value generated by the decision error calculator 1010; iₑₛₜ(n) is the estimate value generated by the decision error estimator 1020; e′(n) is an error value between a current decision error value generated by the decision error calculator 1010 and the estimate value; and p is a step size.

In a preferred embodiment, the linear predictor 934 is disabled during the training state and enabled if there is any tap coefficient of the constraint region 222 of the feedback filter 120 is constrained by the updating device 150 during the tracking state. As a result, the equalizing performance of the DFE 900 can be further improved.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A decision feedback equalizer comprising:
a feed-forward filter for filtering an incoming signal to generate a filtered signal;
a feedback filter for generating a feedback signal according to a decision signal;
an operating device, coupled to the feed-forward filter and the feedback filter, for generating an output signal according to the filtered signal and the feedback signal;
a decision device, coupled to the operating device and the feedback filter, for generating the decision signal according to the output signal; and
an updating device coupled to the feedback filter for constraining coefficients of predetermined taps of the feedback filter while updating the tap coefficients of the feedback filter;
wherein each predetermined tap of the feedback filter corresponds to a tap of the feed-forward filter.

2. The decision feedback equalizer of claim 1, wherein the updating device constrains the coefficient of each predetermined tap within a first range during a training state of the decision feedback equalizer, and constrains the coefficient of each predetermined tap within a second range that is narrower than the first range during a tracking state of the decision feedback equalizer.

3. The decision feedback equalizer of claim 2, wherein the updating device gradually narrows the second range during the tracking state.

4. The decision feedback equalizer of claim 3, wherein the updating device comprises:
a constraint level generator for generating a current constraint level corresponding to either the first range or the second range; and
at least one coefficient updater coupled to the constraint level generator for updating the coefficient of a predetermined tap according to the current constraint level.

5. The decision feedback equalizer of claim 4, wherein the constraint level generator comprises:
a subtracter for subtracting a predetermined value from a preceding constraint level to generate a candidate constraint level;
a first selector coupled to the subtracter for selectively outputting the candidate constraint level or a second predetermined level as a first output;
a second selector coupled to the first selector for selectively outputting a first predetermined level or the first output as the current constraint level; and
a control unit coupled to the first and second selectors for controlling the operations of the first and second selectors.

6. The decision feedback equalizer of claim 4, wherein the coefficient updater comprises:
a calculating unit for calculating a tap coefficient according to a coefficient gradient and a preceding tap coefficient of a corresponding predetermined tap of the feedback filter; and
a limiter coupled to the calculating unit for limiting the absolute value of the tap coefficient generated by the calculating unit according to the current constraint level to generate a current tap coefficient for the predetermined tap.

7. The decision feedback equalizer of claim 3, wherein the updating device applies a leakage function to erode a preceding tap coefficient of a corresponding predetermined tap of the feedback filter to generate a current tap coefficient for the predetermined tap.

8. The decision feedback equalizer of claim 7, wherein the updating device comprises:
a multiplier for multiplying a preceding tap coefficient of a corresponding predetermined tap of the feedback filter by an adjusting factor to generate a product; and
an adder coupled to the multiplier for adding the product to a coefficient gradient to generate the current tap coefficient.

9. The decision feedback equalizer of claim 3, wherein the updating device comprises:
a calculating unit for calculating a tap coefficient according to a coefficient gradient and a preceding tap coefficient of a corresponding predetermined tap of the feedback filter;
an operating unit coupled to the calculating unit for applying a sign function on the tap coefficient generated by the calculating unit to generate a sign value;
a multiplier coupled to the operating unit for multiplying the sign value by a predetermined value to generate a product; and
a subtracter coupled to the multiplier for subtracting the product from the preceding tap coefficient to generate a current tap coefficient for the predetermined tap.

10. The decision feedback equalizer of claim 1, wherein the feed-forward filter comprises a first tap set, a second tap set, and a main tap positioned between the first and second tap sets, and the updating device constrains coefficients of a plurality of predetermined taps of the feedback filter while updating the tap coefficients of the feedback filter in which the plurality of predetermined taps correspond to taps of the second tap set of the feed-forward filter.

11. The decision feedback equalizer of claim 10, wherein the first tap set of the feed-forward filter comprises a tap for receiving the incoming signal.

12. The decision feedback equalizer of claim 10, wherein the tap number of the plurality of predetermined taps is less than the tap number of the second tap set.

13. The decision feedback equalizer of claim 12, wherein the sum of the tap number of the plurality of predetermined taps and the tap number of the second tap set is less than the total tap number of the feedback filter.

14. The decision feedback equalizer of claim 10, wherein the sum of the tap number of the plurality of predetermined taps and the tap number of the second tap set is less than the total tap number of the feedback filter.

15. The decision feedback equalizer of claim 1, wherein the operating device comprises:
an adder for adding the filtered signal and the feedback signal to generate a data signal;
a linear predictor, coupled to the adder and the decision device, for estimating decision errors made by the decision device according to the data signal and the decision signal; and
a subtracter, coupled to the adder and the linear predictor, for subtracting the estimated decision errors from the data signal to generate the output signal.

16. The decision feedback equalizer of claim 15, wherein the linear predictor comprises:
a decision error calculator for calculating a plurality of decision error values according to the data signal and the decision signal;
a decision error estimator coupled to the decision error calculator for generating an estimate value according to the plurality of decision error values and a plurality of tap coefficients;
a subtracter, coupled to the decision error calculator and the decision error estimator, for subtracting the estimate value from a decision error value generated by the decision error calculator to generate an error value; and
a coefficient updating device, coupled to the subtracter and the decision error estimator, for updating the plurality of tap coefficients of the decision error estimator according to the error value and the plurality of decision error values.

17. The decision feedback equalizer of claim 16, wherein the decision error estimator is a digital filter.

18. A method for equalizing an incoming signal, comprising:
utilizing a feed-forward filter to filter the incoming signal to generate a filtered signal;
utilizing a feedback filter to generate a feedback signal according to a decision signal;
generating an output signal according to the filtered signal and the feedback signal;
generating the decision signal according to the output signal; and
constraining coefficients of predetermined taps of the feedback filter while updating the tap coefficients of the feedback filter in which each predetermined tap of the feedback filter corresponds to a tap of the feed-forward filter.

19. The method of claim 18, wherein the constraining step comprises:
constraining the coefficient of each predetermined tap within a first range during a training state; and
constraining the coefficient of each predetermined tap within a second range that is narrower than the first range during a tracking state.

20. The method of claim 19, wherein the second range is gradually narrowed during the tracking state.

21. The method of claim 20, wherein the constraining step further comprises:
generating a current constraint level corresponding to either the first range or the second range; and
updating the coefficient of a predetermined tap according to the current constraint level.

22. The method of claim 21, wherein the step of generating the current constraint level comprises:
subtracting a predetermined value from a preceding constraint level to generate a candidate constraint level;
selectively outputting the candidate constraint level or a second predetermined level as a first output; and
selectively outputting a first predetermined level or the first output as the current constraint level.

23. The method of claim 21, wherein the step of updating the coefficient of the predetermined tap comprises:
calculating a tap coefficient according to a coefficient gradient and a preceding tap coefficient of a corresponding predetermined tap of the feedback filter; and
limiting the absolute value of the tap coefficient according to the current constraint level to generate a current tap coefficient for the predetermined tap.

24. The method of claim 20, wherein the constraining step comprises:
applying a leakage function to erode a preceding tap coefficient of a corresponding predetermined tap of the feedback filter to generate a current tap coefficient for the predetermined tap.

25. The method of claim 24, wherein the constraining step comprises:
multiplying a preceding tap coefficient of a corresponding predetermined tap of the feedback filter by an adjusting factor to generate a product; and
adding the product to a coefficient gradient to generate the current tap coefficient.

26. The method of claim 20, wherein the constraining step comprises:
calculating a tap coefficient according to a coefficient gradient and a preceding tap coefficient of a corresponding predetermined tap of the feedback filter;
applying a sign function on the tap coefficient to generate a sign value;
multiplying the sign value by a predetermined value to generate a product; and
subtracting the product from the preceding tap coefficient to generate a current tap coefficient for the predetermined tap.

27. The method of claim 18, wherein the feed-forward filter comprises a first tap set, a second tap set, and a main tap positioned between the first and second tap sets, and the constraining step comprises:
constraining coefficients of a plurality of predetermined taps of the feedback filter while updating the tap coefficients of the feedback filter in which the plurality of the predetermined taps correspond to taps of the second tap set of the feed-forward filter.

28. The method of claim 27, wherein the first tap set of the feed-forward filter comprises a tap for receiving the incoming signal.

29. The method of claim 27, wherein the tap number of the plurality of predetermined taps is less than the tap number of the second tap set.

30. The method of claim 29, wherein the sum of the tap number of the plurality of predetermined taps and the tap number of the second tap set is less than the total tap number of the feedback filter.

31. The method of claim 27, wherein the sum of the tap number of the plurality of predetermined taps and the tap number of the second tap set is less than the total tap number of the feedback filter.

32. The method of claim 18, wherein the step of generating the output signal comprises:
adding the filtered signal and the feedback signal to generate a data signal;
estimating decision errors according to the data signal and the decision signal; and
subtracting the estimated decision errors from the data signal to generate the output signal.

33. The method of claim 32, wherein the estimating step comprises:
calculating a plurality of decision error values according to the data signal and the decision signal;
utilizing a decision error estimator to generate an estimate value according to the plurality of decision error values and a plurality of tap coefficients;
subtracting the estimate value from a decision error value to generate an error value; and
updating the plurality of tap coefficients of the decision error estimator according to the error value and the plurality of decision error values.
